(19) United States
(12) Patent Application Publication
(10) Pub. No.: US 2026/0112587 A1
(43) Pub. Date: Apr. 23, 2026

(54) CLEANING METHOD FOR PLASMA PROCESSING APPARATUS AND PLASMA PROCESSING APPARATUS

(71) Applicant: Tokyo Electron Limited, Tokyo (JP)

(72) Inventor: Wataru SHIMIZU, Miyagi (JP)

(73) Assignee: Tokyo Electron Limited, Tokyo (JP)

(21) Appl. No.: 19/426,145

(22) Filed: Dec. 19, 2025

Related U.S. Application Data
(63) Continuation of application No. PCT/JP2024/022242, filed on Jun. 19, 2024.

(30) Foreign Application Priority Data
Jun. 27, 2023 (JP) 2023-104741

(51) Int. Cl. H01J 37/32

(52) U.S. Cl. CPC H01J 37/32862; H01J 37/32449; H01J 37/32935

(57) ABSTRACT

A cleaning method for a plasma processing apparatus includes introducing a cleaning gas into a chamber of the plasma processing apparatus, generating a plasma in the chamber to perform a first cleaning under a first condition, and generating a plasma in the chamber to perform a second cleaning under a second condition. At least one of the first condition and the second condition is adjusted such that a first ratio of an inner sheath thickness to an outer sheath thickness in a sheath of the plasma and a second ratio of an inner sheath thickness to an outer sheath thickness in a sheath of the other plasma are different from each other.

### CROSS-REFERENCE TO RELATED APPLICATIONS

This application is a bypass continuation application of international application No. PCT/JP2024/022242, having an international filing date of Jun. 19, 2024 and designating the United States. The international application is based upon and claims the benefit of priority from Japanese Patent Application No. 2023-104741, filed on Jun. 27, 2023. The entire contents of both prior applications are incorporated herein by reference.

### TECHNICAL FIELD

The present disclosure relates to a cleaning method for a plasma processing apparatus and a plasma processing apparatus.

### BACKGROUND

PTL 1 discloses a plasma processing apparatus provided with an upper electrode. The upper electrode includes a first upper electrode and a second upper electrode that is provided around the first upper electrode to surround the first upper electrode and that is insulated from the first upper electrode.

### CITATION LIST

### Patent Documents

PTL 1: JP2017-112275A

### SUMMARY

The technique according to the present disclosure efficiently cleans a plasma processing apparatus.

An aspect of the present disclosure is a cleaning method for a plasma processing apparatus, which includes introducing a cleaning gas into a chamber of the plasma processing apparatus, generating a plasma in the chamber to perform a first cleaning under a first condition, and generating an other plasma in the chamber to perform a second cleaning under a second condition. At least one of the first condition and the second condition is adjusted such that a first ratio of an inner sheath thickness to an outer sheath thickness in a sheath of the plasma and a second ratio of an inner sheath thickness to an outer sheath thickness in a sheath of the other plasma are different from each other.

According to the present disclosure, the plasma processing apparatus can be efficiently cleaned.

### BRIEF DESCRIPTION OF DRAWINGS

FIG. 1 is a diagram schematically illustrating a configuration of a plasma processing system.

FIG. 2 is a diagram illustrating a state where a gap between an inner upper electrode and an outer upper electrode is cleaned.

FIG. 3 is a diagram illustrating a state where the gap between the inner upper electrode and the outer upper electrode is cleaned.

FIG. 4 is a diagram illustrating a state where the gap between the inner upper electrode and the outer upper electrode is cleaned.

FIG. 5 is a diagram illustrating an example of a cleaning method for the gap between the inner upper electrode and the outer upper electrode.

FIG. 6 is a diagram illustrating behaviors of deposits removed from the gap.

FIG. 7 is a diagram illustrating an example of a cleaning method for a gap between an inner upper electrode and an outer upper electrode in another embodiment.

FIG. 8 is a diagram illustrating a state where the gap between the inner upper electrode and the outer upper electrode is cleaned in the other embodiment.

FIG. 9 is a diagram illustrating a state where the gap between the inner upper electrode and the outer upper electrode is cleaned in the other embodiment.

FIG. 10 is a diagram illustrating a state where the gap between the inner upper electrode and the outer upper electrode is cleaned in the other embodiment.

FIG. 11A is a first diagram illustrating a state where a gap between an electrostatic chuck and an edge ring is cleaned.

FIG. 11B is a second diagram illustrating the state where the gap between the electrostatic chuck and the edge ring is cleaned.

FIG. 11C is a third diagram illustrating the state where the gap between the electrostatic chuck and the edge ring is cleaned.

FIG. 12A is a diagram illustrating a state where the gap between the electrostatic chuck and the edge ring is cleaned.

FIG. 12B is a diagram illustrating a state where the gap between the electrostatic chuck and the edge ring is cleaned.

FIG. 12C is a diagram illustrating a state where the gap between the electrostatic chuck and the edge ring is cleaned.

### DETAILED DESCRIPTION

In a step of producing a semiconductor device, a semiconductor substrate (hereinafter referred to as a “substrate”) is subjected to various types of plasma processing, such as an etching process, a film formation process, and a diffusion process. In the plasma processing, a plasma is generated by exciting a processing gas, and the substrate is processed by the plasma.

The plasma processing is performed using, for example, a capacitively coupled plasma (CCP) plasma processing apparatus. The plasma processing apparatus includes a chamber, a substrate support, a plasma generator, and the like. The plasma processing apparatus further includes an upper electrode that configures at least a part of a ceiling portion of the chamber, and a lower electrode provided in the substrate support. For example, the upper electrode includes a first upper electrode (an inner upper electrode) and a second upper electrode (an outer upper electrode). The outer upper electrode is provided to surround a periphery of the inner upper electrode, and the inner upper electrode and the outer upper electrode are insulated from each other.

In the plasma processing, reaction products are generated. The reaction products adhere to a sidewall of the chamber, a member in the chamber, or the like, and are deposited as deposits. In particular, for example, when deposits are deposited in a tiny gap formed between the inner upper electrode and the outer upper electrode, the gap may be narrowed to cause an abnormal discharge. Therefore, to remove the deposits, dry cleaning using a plasma is performed in the chamber. That is, in the dry cleaning, a cleaning gas is excited to generate a plasma, and the deposits are removed using the plasma. Specifically, in the dry cleaning, the deposits are removed by a chemical reaction caused by radicals and a physical reaction (sputtering) caused by ions.

However, in the dry cleaning in the related art, for example, a DC voltage applied to the inner upper electrode and the outer upper electrode is constant, and since ions are incident in one direction onto the tiny gap between the inner upper electrode and the outer upper electrode, it is less likely to remove the deposits that adhere to the gap. The deposits are, for example, compounds containing yttrium (Y), and such deposits are less likely to be removed chemically. Therefore, the cleaning method in the related art has room for improvement.

The technique according to the present disclosure efficiently cleans a plasma processing apparatus. Hereinafter, a plasma processing apparatus and a dry cleaning method for a plasma processing apparatus according to the present embodiment will be described with reference to the drawings. The same reference numerals will be given to elements having substantially the same functional configurations throughout the specification and the drawings, and redundant description thereof will be omitted.

### <Plasma Processing System and Plasma Processing Apparatus>

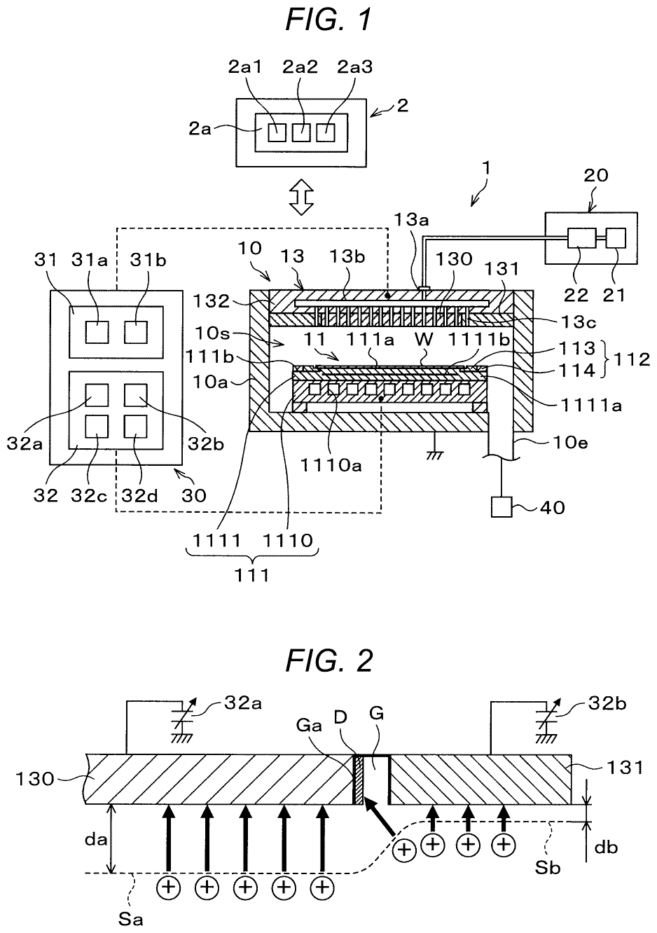

Hereinafter, a configuration example of the plasma processing system will be described. FIG. 1 is a diagram illustrating a configuration example of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. The plasma processing apparatus 1 includes the substrate support 11 and a gas introducer. The gas introducer is configured to introduce at least one processing gas or at least one cleaning gas into the plasma processing chamber 10. The gas introducer includes a shower head assembly 13. The substrate support 11 is disposed in the plasma processing chamber 10. The shower head assembly 13 is disposed above the substrate support 11. In one embodiment, the shower head assembly 13 constitutes at least a part of a ceiling of the plasma processing chamber 10. The shower head assembly 13 is supported by a sidewall 10a of the plasma processing chamber 10 through an insulating member (not illustrated). The plasma processing chamber 10 has a plasma processing space 10s defined by the shower head assembly 13, the sidewall 10a of the plasma processing chamber 10, and the substrate support 11. The plasma processing chamber 10 has at least one gas supply port for supplying at least one processing gas or at least one cleaning gas into the plasma processing space 10s, and at least one gas exhaust port for exhausting the gas from the plasma processing space. The plasma processing chamber 10 is grounded. The shower head assembly 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32 to be described below may be disposed inside the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one embodiment, the one or more annular members include one or more edge rings 113 and at least one cover ring 114. The edge ring 113 is provided in an annular shape to surround the substrate W on the main body 111. The cover ring 114 is provided in an annular shape to surround the edge ring 113. The edge ring 113 is formed of a conductive material or an insulating material, and, for example, is formed of Si or SiC in the case of the conductive material. The cover ring 114 is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head assembly 13 is configured to introduce at least one processing gas or at least one cleaning gas from the gas supply 20 into the plasma processing space 10s. The shower head assembly 13 has at least one gas supply port 13a, at least one gas diffusion chamber 13b, and gas introduction ports 13c. The processing gas or the cleaning gas supplied to the gas supply port 13a passes through the gas diffusion chamber 13b and is introduced into the plasma processing space 10s from the gas introduction ports 13c. The gas introducer may include, in addition to the shower head assembly 13, one or more side gas injectors (SGI) that are attached to one or more openings formed in the sidewall 10a.

The shower head assembly 13 includes at least one upper electrode. In one embodiment, the shower head assembly 13 includes an inner upper electrode 130, an outer upper electrode 131, and an electrode support 132. The inner upper electrode 130 is provided above the central region 111a of the main body 111. The inner upper electrode 130 is an electrode plate having a substantially circular disk shape. The outer upper electrode 131 is provided to surround the inner upper electrode 130 above the annular region 111b (the ring assembly 112) of the main body 111. The outer upper electrode 131 is an electrode plate having a substantially annular shape. The inner upper electrode 130 and the outer upper electrode 131 are each formed of a conductive material, and are formed of, for example, Si or SiC. The electrode support 132 detachably supports the inner upper electrode 130 and the outer upper electrode 131. The electrode support 132 is formed of a conductive material, and is formed of, for example, aluminum.

The gas supply 20 may include at least one gas source 21 and at least one flow rate controller 22. In one embodiment, the gas supply 20 is configured to supply at least one processing gas or at least one cleaning gas from the respective corresponding gas sources 21 to the shower head assembly 13 via the respective corresponding flow rate controllers 22. The flow rate controller 22 may include, for example, a mass flow controller or a pressure-controlled flow rate controller. The gas supply 20 may further include one or more flow rate modulation devices that modulate or pulse a flow rate of at least one processing gas or at least one cleaning gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode 130, 131. Accordingly, a plasma is formed from the at least one processing gas or the at least one cleaning gas supplied into the plasma processing space 10s. Therefore, the RF power source 31 may function as at least a part of the plasma generator configured to generate a plasma from one or more processing gases or one or more cleaning gases in the plasma processing chamber 10. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to the at least one lower electrode and/or the at least one upper electrode 130, 131 via the at least one impedance matching circuit, and is configured to generate a plasma generation source RF signal (source RF power). In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to the at least one lower electrode and/or the at least one upper electrode 130, 131.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

The power source 30 may include the DC power source 32 coupled to the plasma processing chamber 10. The DC power source 32 includes circuitry such as a first DC generator 32a, a second DC generator 32b, a third DC generator 32c, and a fourth DC generator 32d. In one embodiment, the first DC generator 32a is connected to the inner upper electrode 130 and is configured to generate a first DC signal. The generated first DC signal is applied to the inner upper electrode 130. In one embodiment, the second DC generator 32b is connected to the outer upper electrode 131 and is configured to generate a second DC signal. The generated second DC signal is applied to the outer upper electrode 131. In one embodiment, the third DC generator 32c is connected to the at least one lower electrode and is configured to generate a third DC signal. The generated third DC signal is applied to the at least one lower electrode. In one embodiment, the fourth DC generator 32d is connected to the one or more edge rings 113 and is configured to generate a fourth DC signal. The generated fourth DC signal is applied to the one or more edge rings 113.

In various embodiments, at least one of the first to third DC signals may be pulsed. In this case, a sequence of voltage pulses is applied to the at least one upper electrode 130, 131 and/or the at least one lower electrode. The voltage pulses may each have a rectangular, trapezoidal, or triangular pulse waveform or a combination thereof. In one embodiment, a waveform generator for generating the sequence of voltage pulses from a DC signal is connected between the first DC generator 32a and the inner upper electrode 130. Accordingly, the first DC generator 32a and the waveform generator form a voltage pulse generator. When the second DC generator 32b and the waveform generator form the voltage pulse generator, the voltage pulse generator is connected to the outer upper electrode 131. When the third DC generator 32c and the waveform generator form the voltage pulse generator, the voltage pulse generator is connected to the at least one lower electrode. The voltage pulse may have a positive polarity or a negative polarity. The sequence of the voltage pulses may include one or more positive voltage pulses and one or more negative voltage pulses in one cycle. The first to third DC generators 32a to 32c may be provided in addition to the RF power source 31, and the third DC generator 32c may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

The controller 2 includes circuitry that processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include circuits such as a processor 2a1, a storage 2a2, and a communication interface 2a3. The controller 2 is implemented, for example, by a computer 2a. The processor 2a1 may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### <Plasma Processing Method>

Next, plasma processing performed using the plasma processing apparatus 1 configured as described above will be described.

First, the substrate W is loaded into the plasma processing chamber 10, and the substrate W is placed on the electrostatic chuck 1111 of the substrate support 11. Next, a voltage is applied to the electrostatic electrode 1111b of the electrostatic chuck 1111. Accordingly, the substrate W is attracted and held by the electrostatic chuck 1111 with an electrostatic force.

When the substrate W is attracted and held by the electrostatic chuck 1111, an inside of the plasma processing chamber 10 is decompressed to a desired vacuum level. Then, the processing gas is supplied from the gas supply 20 to the plasma processing space 10s via the shower head assembly 13. Further, the source RF power for plasma generation is supplied from the first RF generator 31a to the lower electrode, and thus the processing gas is excited to generate plasma. At this time, the bias RF power may be supplied from the second RF generator 31b. Then, in the plasma processing space 10s, the substrate W is subjected to plasma processing by the action of the generated plasma.

### <Cleaning Method>

In the plasma processing, reaction products are generated. The reaction products adhere to the sidewall 10a of the plasma processing chamber 10, a member in the plasma processing chamber 10, or the like, and are deposited as deposits. Therefore, to remove the deposits, dry cleaning using a plasma is performed in the plasma processing chamber 10. That is, in the dry cleaning, a cleaning gas is excited to generate a plasma, and the deposits are removed using the plasma. The type of the cleaning gas is appropriately selected according to the type of the deposits. For example, when the deposits are yttrium compounds, an O₂ gas is used as the cleaning gas.

The dry cleaning includes a case where the dry cleaning is performed in a state where a dummy substrate is supported by the substrate support 11 and a case where the dry cleaning is performed in a state where the dummy substrate is not supported by the substrate support 11 (substrate-less dry cleaning). In either dry cleaning, first, the inside of the plasma processing chamber 10 is decompressed to a desired vacuum level, as in the plasma processing. Next, the cleaning gas is supplied from the gas supply 20 to the plasma processing space 10s via the shower head assembly 13. The source RF power for plasma generation is supplied from the first RF generator 31a to the lower electrode. Accordingly, the cleaning gas is excited to generate a plasma. At this time, the bias RF power may be supplied from the second RF generator 31b. Then, the inside of the plasma processing chamber 10 is cleaned by the action of the generated plasma in the plasma processing space 10s.

### [Cleaning of Upper Electrode]

When the reaction products adhere to a tiny gap G formed between the inner upper electrode 130 and the outer upper electrode 131 and the deposits are deposited therein, the gap G may be narrowed to cause an abnormal discharge. However, in the dry cleaning in the related art, for example, a DC voltage applied to the upper electrode is constant, and since ions are incident in one direction onto the gap G, it is less likely to remove the deposits that adhere to the gap G. Therefore, in the present embodiment, a sheath thickness of the plasma below the inner upper electrode 130 and a sheath thickness of the plasma below the outer upper electrode 131 are controlled, respectively, and an incidence direction of the ions to the gap G is controlled, thereby removing the deposits that adhere to the gap G.

Here, the sheath thickness of the plasma can be calculated by, for example, the following equation (1).

$$\begin{matrix}[ Equation 1 ] & \\ Sheath Thickness = \frac{\sqrt{2}}{3} ( \frac{{ε}_{0} \cdot Te}{e \cdot Ne} ) {( \frac{2 {V}_{d c}}{Te} )}^{\frac{3}{4}} & ( 1 )\end{matrix}$$

Here, V_{dc} is a self-bias voltage (a self-bias potential), Te is a plasma temperature, Ne is a plasma density, ε₀ is a dielectric constant of a vacuum, and e is an elementary charge.

According to the above equation (1), when the self-bias voltage is large, the sheath thickness increases, and when the self-bias voltage is small, the sheath thickness decreases. Therefore, in the present embodiment, a DC voltage (hereinafter referred to as an “inner DC voltage”) applied from the first DC generator 32a to the inner upper electrode 130 is controlled to control a self-bias voltage of the inner upper electrode 130. A DC voltage (hereinafter referred to as an “outer DC voltage”) applied from the second DC generator 32b to the outer upper electrode 131 is controlled to control a self-bias voltage of the outer upper electrode 131.

FIGS. 2 to 4 are diagrams illustrating a state where the gap G between the inner upper electrode 130 and the outer upper electrode 131 is cleaned. In the following description, a sheath of a plasma generated below the inner upper electrode 130 will be referred to as an inner sheath Sa, and a sheath of a plasma generated below the outer upper electrode 131 will be referred to as an outer sheath Sb. A thickness da of the inner sheath Sa is a distance from the plasma to a lower surface of the inner upper electrode 130, and a thickness db of the outer sheath Sb is a distance from the plasma to a lower surface of the outer upper electrode 131.

FIG. 2 is a diagram illustrating a case where the inner DC voltage is larger than the outer DC voltage. In the following description, this cleaning condition will be referred to as a first condition. In this case, the thickness da of the inner sheath Sa is larger than the thickness db of the outer sheath Sb. Accordingly, the incidence direction (arrows in the drawing) of the ions to the gap G is inclined toward an inner upper electrode 130 side from a vertical direction, and the ions are incident on a side surface Ga of the gap G on the inner upper electrode 130 side. Then, this side surface Ga becomes a cleaning target region (a hatched region in the drawing), and deposits D that adhere to the side surface Ga are removed by the ions. The removed deposits D are exhausted from the gas exhaust port 10e provided in a bottom of the plasma processing chamber 10.

By controlling a ratio da/db (hereinafter referred to as a “thickness ratio”) of the thickness da of the inner sheath Sa to the thickness db of the outer sheath Sb, it is possible to adjust an inclination angle from the vertical direction in the incidence direction of the ions. That is, when the thickness ratio da/db is large, the inclination angle of the ions increases. Instead of the thickness ratio da/db, a difference between the thickness da of the inner sheath Sa and the thickness db of the outer sheath Sb may be controlled.

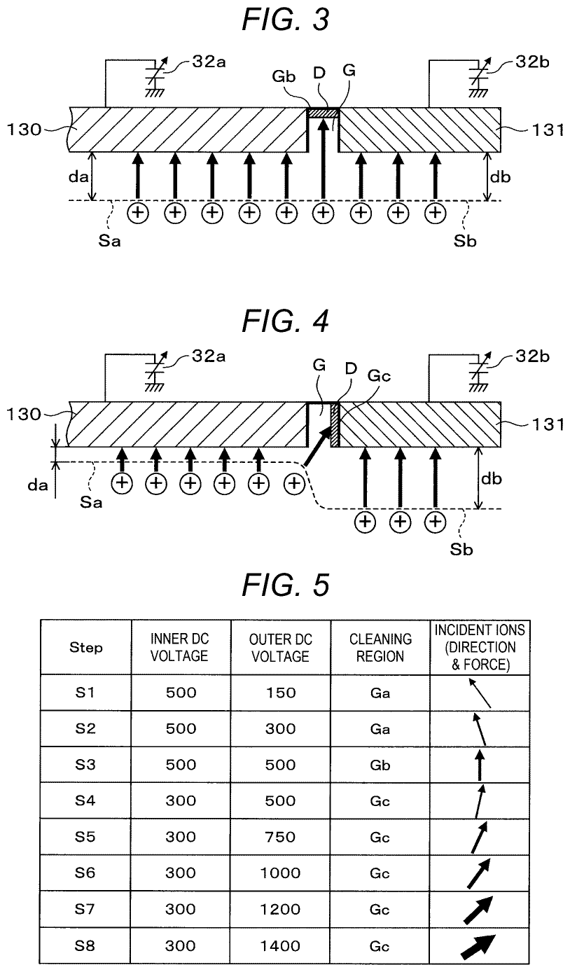

FIG. 3 is a diagram illustrating a case where the inner DC voltage and the outer DC voltage are the same. In the following description, this cleaning condition will be referred to as a second condition. In this case, the thickness da of the inner sheath Sa and the thickness db of the outer sheath Sb are the same. Accordingly, the incidence direction (the arrows in the drawing) of the ions to the gap G becomes the vertical direction, and the ions are incident on an upper surface Gb of the gap G. Then, the upper surface Gb becomes a cleaning target region (a hatched region in the drawing), and the deposits D that adhere to the upper surface Gb are removed by the ions and are exhausted from the gas exhaust port 10e.

FIG. 4 is a diagram illustrating a case where the inner DC voltage is less than the outer DC voltage. In the following description, this cleaning condition will be referred to as a third condition. In this case, the thickness da of the inner sheath Sa is less than the thickness db of the outer sheath Sb. Accordingly, the incidence direction (arrows in the drawing) of the ions to the gap G is inclined toward an outer upper electrode 131 side from the vertical direction, and the ions are incident on a side surface Gc of the gap G on the outer upper electrode 131 side. Then, the side surface Gc becomes a cleaning target region (a hatched region in the drawing), and the deposits D that adhere to the side surface Gc are removed by the ions and are exhausted from the gas exhaust port 10e. In this case, when the thickness ratio da/db of the sheath is small, the inclination angle of the ions increases.

In the present embodiment, after the cleaning gas is introduced into the plasma processing space 10s, a first cleaning (FIG. 2) under the first condition, a second cleaning (FIG. 3) under the second condition, and a third cleaning (FIG. 4) under the third condition are sequentially performed. In the first to third conditions, the inner DC voltage and the outer DC voltage are varied as described above, and other conditions, for example, the source RF power and the bias RF power supplied to the lower electrode are the same. In this case, the side surface Ga, the upper surface Gb, and the side surface Gc in the gap G can be sequentially cleaned, and the gap G can be efficiently cleaned in a wide range. As a result, it is possible to prevent the abnormal discharge between the inner upper electrode 130 and the outer upper electrode 131.

FIG. 5 is a diagram illustrating an example of a cleaning method for the gap G. In FIG. 5, a value of the inner DC voltage and a value of the outer DC voltage are examples only, and are not limited thereto. A cleaning region indicates a cleaning target region from which the deposits D are removed. An arrow of incident ions indicates the incidence direction of the ions to the gap G and a removing force (hereinafter referred to as “sputtering force”) against the deposits D by the ions. The incidence direction of the ions is indicated by an arrow, and similarly to FIGS. 2 to 4, the left side from the vertical direction is the inner upper electrode 130 side, and the right side from the vertical direction is the outer upper electrode 131. The sputtering force of the ions is indicated by a thickness of an arrow.

Steps S1 and S2 are the first cleaning under the first condition (FIG. 2). The inner DC voltage is larger than the outer DC voltage, the incidence direction of the ions is inclined from the vertical direction toward the inner upper electrode 130 side, and the side surface Ga is cleaned. In steps S1 and S2, the inner DC voltage is fixed to 500 V, and the outer DC voltage is increased to 150 V and 300 V. That is, the outer DC voltage is varied (swept) in stages toward step S3 to be described later. Accordingly, the thickness ratio da/db of the sheath is also varied in stages and decreases, and the inclination angle of the ions decreases in stages. As the outer DC voltage increases, the sputtering force of the ions increases.

Step S3 is the second cleaning under the second condition (FIG. 3). The inner DC voltage and the outer DC voltage are the same 500 V, the incidence direction of the ions is the vertical direction, and the upper surface Gb is cleaned.

Steps S4 to S8 are the third cleaning under the third condition (FIG. 4). The inner DC voltage is less than the outer DC voltage, the incidence direction of the ions is inclined from the vertical direction toward the outer upper electrode 131 side, and the side surface Gc is cleaned. In steps S4 to S8, the inner DC voltage is fixed at 300 V, and the outer DC voltage is varied in stages, increasing from 500 V to 1400 V. Accordingly, the thickness ratio da/db of the sheath is also varied in stages and decreases, and the inclination angle of the ions increases in stages. As the outer DC voltage increases, the sputtering force of the ions increases.

According to the present embodiment, by controlling the inner DC voltage and the outer DC voltage, more specifically, by controlling a balance (a ratio) between the inner DC voltage and the outer DC voltage, the thickness ratio da/db of the sheath can be controlled to freely control the incidence direction of the ions to the gap G. Then, by sequentially performing the first to third cleanings, the side surface Ga, the upper surface Gb, and the side surface Gc in the gap G are sequentially cleaned, and the deposits D on the side surface Ga, the upper surface Gb, and the side surface Gc can be efficiently removed.

Further, by controlling magnitudes of the inner DC voltage and the outer DC voltage, the sputtering force of the ions can be controlled. Accordingly, it is possible to more efficiently remove the deposits D on the side surface Ga, the upper surface Gb, and the side surface Gc.

In the first cleaning (steps S1 and S2), the outer DC voltage is varied in stages and the inclination angle of the ions is varied in stages, and therefore, the ions collide with the entire side surface Ga, and the side surface Ga can be cleaned in a wide range. In the third cleaning (steps S4 to S8), since the outer DC voltage is varied in stages, the inclination angle of the ions is varied in stages, and therefore, the ions collide with the entire side surface Gc, and the side surface Gc can be cleaned in a wide range.

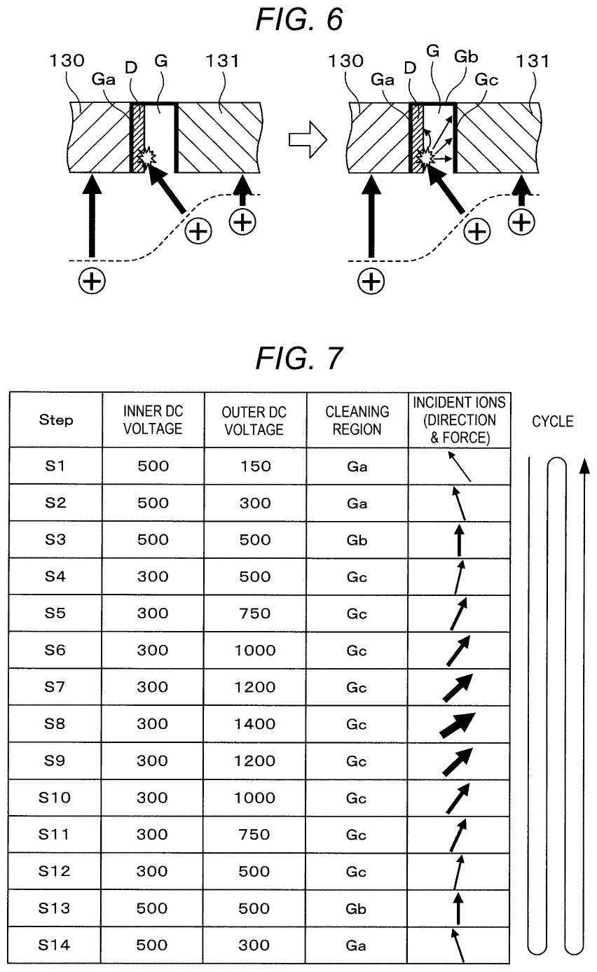

Here, for example, when the side surface Ga of the gap G is cleaned as illustrated in FIG. 6, the deposits D removed from the side surface Ga may not be exhausted from the gap G and may adhere to the upper surface Gb or the side surface Gc again. Therefore, the first cleaning (FIG. 2) under the first condition, the second cleaning (FIG. 3) under the second condition, and the third cleaning (FIG. 4) under the third condition are preferably repeated.

FIG. 7 is a diagram illustrating an example of a cleaning method for the gap G according to another embodiment. In the present embodiment, steps S9 to S14 are performed subsequent to steps S1 to S8 of the above-described embodiment illustrated in FIG. 5.

Steps S9 to S12 are a cleaning under the third condition (FIG. 4) continuously performed from step S8, and the side surface Gc is cleaned. In steps S9 to S12, the inner DC voltage is continuously fixed to 300 V from step S8, and the outer DC voltage is decreased in stages from step S8, specifically, decreases in stages from 1200 V to 500 V. That is, in the third cleaning, after the outer DC voltage is increased in stages in steps S4 to S8, the outer DC voltage is decreased in stages in steps S8 to S12. Accordingly, in steps S9 to S12, the thickness ratio da/db of the sheath also increases in stages, and the inclination angle of the ions decreases in stages. As the outer DC voltage decreases, the sputtering force of the ions decreases.

In step S13, the second cleaning under the second condition (FIG. 3) is performed, and the upper surface Gb is cleaned. In step S13, the inner DC voltage is set to 500 V larger than that in step S12, and the outer DC voltage is continuously set to 500 V from step S12. That is, in step S13, the inner DC voltage and the outer DC voltage are both 500 V.

In step S14, the first cleaning under the first condition (FIG. 2) is performed, and the side surface Ga is cleaned. In step S14, the inner DC voltage is continuously set to 500 V from step S13, and the outer DC voltage is decreased from step S13, specifically, is set to 300 V.

FIG. 7 illustrates a cleaning cycle of the gap G. That is, in the present embodiment, after steps S1 to S14 described above are performed, steps S14 to S1 are performed in a reverse way, and steps S1 to S14 and steps S14 to S1 are repeated. Then, in the gap G, the cleaning of the side surface Ga, the upper surface Gb, and the side surface Gc, and the cleaning of the side surface Gc, the upper surface Gb, and the side surface Ga are repeated. Therefore, even when the deposits D removed from the gap G adhere again to the gap G as illustrated in FIG. 6, the deposits D can be appropriately removed.

In the cleaning cycle according to the present embodiment, steps S1 to S14 and steps S14 to S1 are repeated. However, the steps in the cleaning cycle are not limited thereto. For example, after steps S1 to S14 are performed, steps S1 to S14 may be performed, that is, steps S1 to S14 may be repeated.

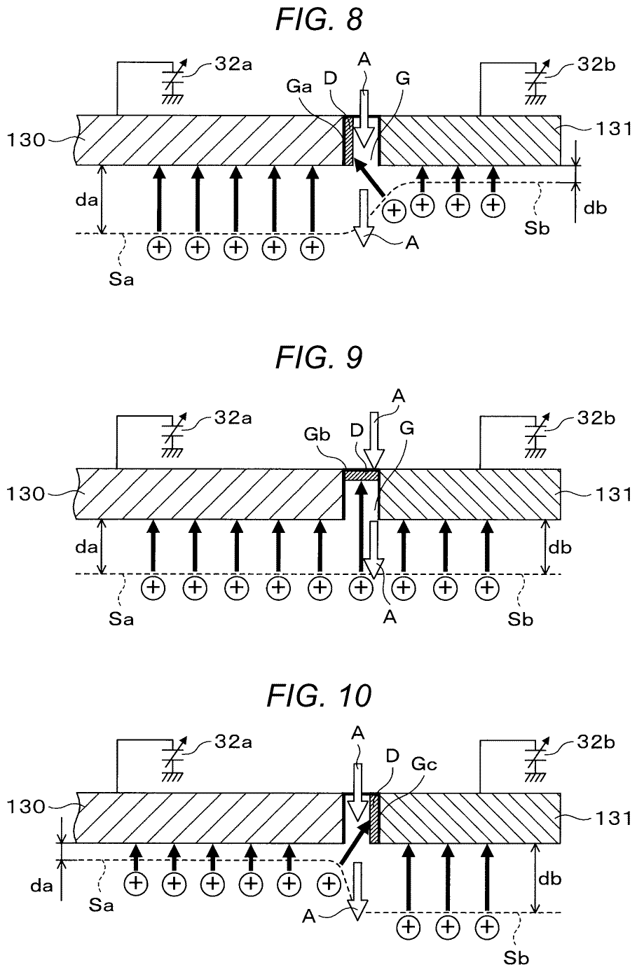

In the above-described embodiment, in cleanings of the gap G, an auxiliary gas A (white arrows in the drawing) may be supplied to the gap G as illustrated in FIGS. 8 to 10. FIG. 8 is a diagram illustrating a case where the first cleaning (FIG. 2) under the first condition is performed, FIG. 9 is a diagram illustrating a case where the second cleaning (FIG. 3) under the second condition is performed, and FIG. 10 is a diagram illustrating a case where the third cleaning (FIG. 4) under the third condition is performed.

The auxiliary gas A is supplied from, for example, the gas supply 20 to the upper surface Gb of the gap G, and flows downward in the gap G. The auxiliary gas A is supplied during at least one of the first cleaning (FIG. 8), the second cleaning (FIG. 9), and the third cleaning (FIG. 10). Then, the deposits D removed from the gap G are exhausted downward by the auxiliary gas A, and are further exhausted from the gas exhaust port 10e. Accordingly, it is possible to prevent the deposits D from adhering again to the gap G as described above.

A type of the auxiliary gas A is not particularly limited, and may be the same as the cleaning gas. For example, an inert gas may be used as the auxiliary gas A, however, a concentration of the cleaning gas in the plasma processing chamber 10 may be reduced in this case, and the plasma generation efficiency may deteriorate. In this respect, by using the same type of gas as the cleaning gas for the auxiliary gas A, the plasma can be efficiently generated. In the present embodiment, the auxiliary gas A is supplied to the gap G from above downward. However, a supply direction is not limited thereto. For example, the auxiliary gas A may be supplied to the gap G from below toward above.

In the above-described embodiment, when controlling the thickness da of the inner sheath Sa and the thickness db of the outer sheath Sb, both the inner DC voltage and the outer DC voltage are varied. However, one of the DC voltages may be fixed, and the other DC voltage may be varied. Even in this case, the thickness ratio da/db of the sheath can be controlled, and as a result, the incidence direction of the ions to the gap G can be controlled.

In the above-described embodiment, when controlling the thickness da of the inner sheath Sa and the thickness db of the outer sheath Sb, the self-bias voltages of the inner upper electrode 130 and the outer upper electrode 131 are controlled by varying both the inner DC voltage and the outer DC voltage. However, the present disclosure is not limited thereto. For example, when the bias RF power from the second RF generator 31b is supplied to the inner upper electrode 130 and the outer upper electrode 131, the self-bias voltages of the inner upper electrode 130 and the outer upper electrode 131 may be controlled by controlling the bias RF power.

According to the above equation (1) for calculating the sheath thickness of the plasma described above, when the plasma density is large, the sheath thickness decreases, and when the plasma density is small, the sheath thickness increases. Therefore, the thickness da of the inner sheath Sa and the thickness db of the outer sheath Sb may be controlled by controlling the density of the plasma formed below the inner upper electrode 130 and the density of the plasma formed below the outer upper electrode 131.

For example, when the source RF power from the first RF generator 31a is supplied to the inner upper electrode 130 and the outer upper electrode 131, the plasma density below the inner upper electrode 130 and the plasma density below the outer upper electrode 131 may be controlled by controlling the source RF power.

For example, to control the plasma density, an electromagnet may be provided on the upper surface of the plasma processing chamber 10 to form a magnetic field in the plasma processing space 10s. In this case, the plasma density below the inner upper electrode 130 and the plasma density below the outer upper electrode 131 may be controlled by controlling the magnetic field formed by the electromagnet above the inner upper electrode 130 and the magnetic field formed by the electromagnet above the outer upper electrode 131.

### [Cleaning of Substrate Support]

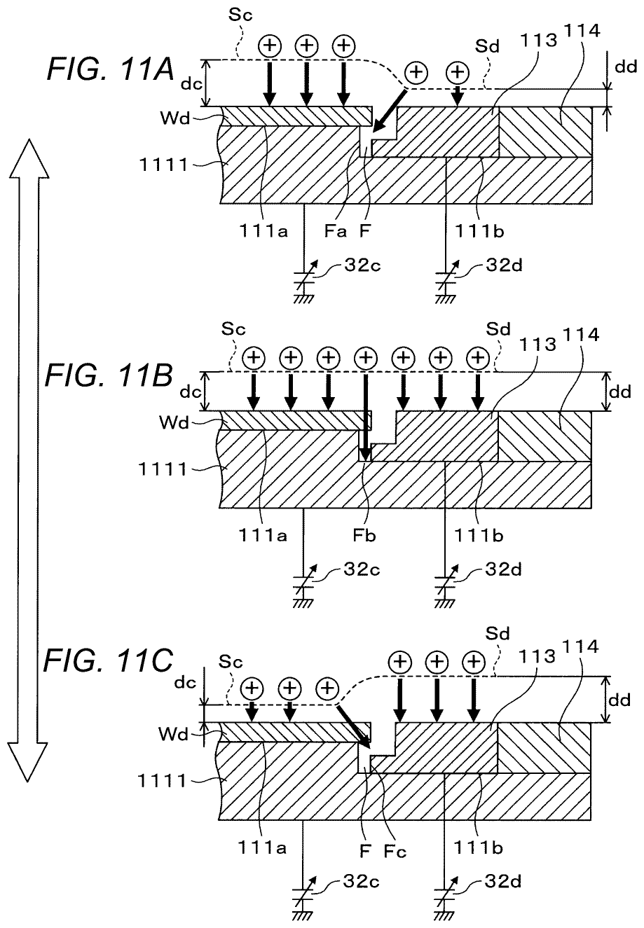

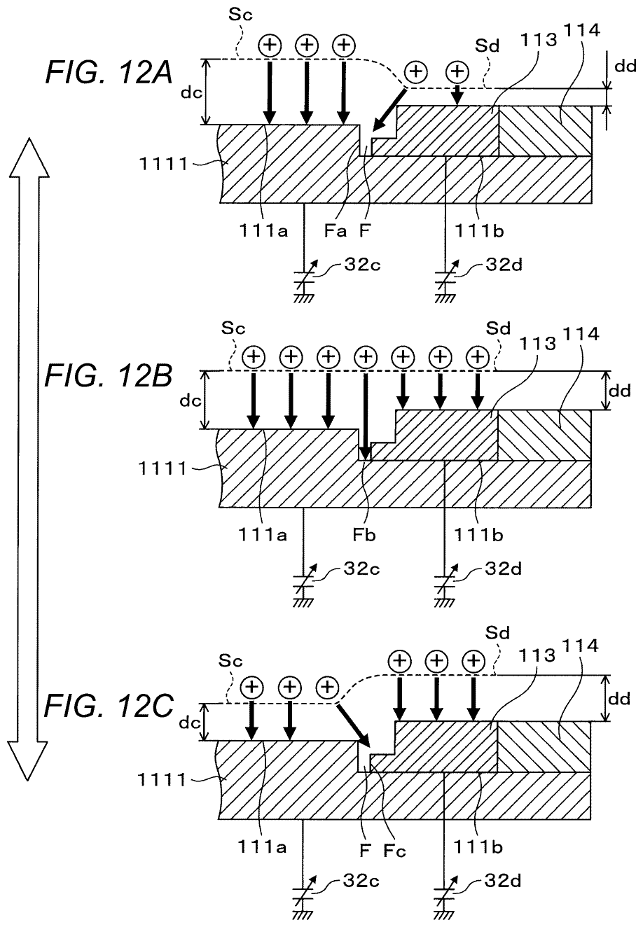

The cleaning method according to the above-described embodiment can also be applied when cleaning a tiny gap F formed between the electrostatic chuck 1111 and the edge ring 113. FIGS. 11A to 11C are diagrams illustrating a state where the gap F is cleaned in a state where a dummy substrate Wd is supported by the substrate support 11. FIGS. 12A to 12C are diagrams illustrating a state where the gap F is cleaned (substrate-less dry cleaning) in a state where the dummy substrate is not supported by the substrate support 11.

As illustrated in FIGS. 11A to 11C and 12A to 12C, the electrostatic chuck 1111 has the central region 111a for supporting the dummy substrate Wd, and the annular region 111b for supporting the ring assembly 112 (the edge ring 113). The central region 111a is provided to protrude beyond the annular region 111b. The gap F is formed between an outer surface of a portion of the electrostatic chuck 1111 corresponding to the central region 111a and an inner surface of the edge ring 113. In the following description, a sheath of a plasma generated above the electrostatic chuck 1111 will be referred to as an inner sheath Sc, and a sheath of a plasma generated above the edge ring 113 will be referred to as an outer sheath Sd. A thickness dc of the inner sheath Sc is a distance from the plasma to an upper surface of the dummy substrate Wd (the electrostatic chuck 1111), and a thickness dd of the outer sheath Sd is a distance from the plasma to an upper surface of the edge ring 113.

Even when cleaning the gap F, the self-bias voltages are controlled to control the thickness dc of the inner sheath Sc and the thickness dd of the outer sheath Sd, respectively, and the incidence direction of the ions to the gap F is controlled. That is, a DC voltage (hereinafter referred to as a “chuck DC voltage”) applied from the third DC generator 32c to the electrostatic chuck 1111 is controlled to control the self-bias voltage of the dummy substrate Wd or the electrostatic chuck 1111. A DC voltage (hereinafter referred to as a “ring DC voltage”) applied from the fourth DC generator 32d to the edge ring 113 is controlled to control the self-bias voltage of the edge ring 113.

FIGS. 11A and 12A are diagrams illustrating a case where the chuck DC voltage is larger than the ring DC voltage. In the following description, this cleaning condition will be referred to as a fourth condition. In this case, the thickness dc of the inner sheath Sc is larger than the thickness dd of the outer sheath Sd. Accordingly, the incidence direction (arrows in the drawing) of the ions to the gap F is inclined toward an electrostatic chuck 1111 side from the vertical direction, and the ions are incident on a side surface Fa of the gap F on the electrostatic chuck 1111 side. Then, this side surface Fa becomes a cleaning target region, and the deposits D that adhere to the side surface Fa are removed by the ions. As can be appreciated, the inclination angle of the ions increase as a thickness ratio dc/dd of the sheath is increases.

FIGS. 11B and 12B are diagrams when the chuck DC voltage and the ring DC voltage are the same. In the following description, this cleaning condition will be referred to as a fifth condition. In this case, the thickness dc of the inner sheath Sc and the thickness dd of the outer sheath Sd are the same. Accordingly, the incidence direction (the arrows in the drawing) of the ions to the gap F becomes the vertical direction, and the ions are incident on a lower surface Fb of the gap F. Then, this lower surface Fb becomes a cleaning target region, and the deposits D that adhere to the lower surface Fb are removed by the ions.

FIGS. 11C and 12C are diagrams when the chuck DC voltage is less than the ring DC voltage. In the following description, this cleaning condition will be referred to as a sixth condition. In this case, the thickness dc of the inner sheath Sc is less than the thickness dd of the outer sheath Sd. Accordingly, the incidence direction (arrows in the drawing) of the ions to the gap F is inclined toward an edge ring 113 side from the vertical direction, and the ions are incident on a side surface Fc of the gap F on the edge ring 113 side. Then, this side surface Fc becomes a cleaning target region, and the deposits D that adhere to the side surface Fc are removed by the ions. In this case, when the thickness ratio dc/dd of the sheath is small, the inclination angle of the ions increases.

In the present embodiment, a fourth cleaning (FIGS. 11A and 12A) under the fourth condition, a fifth cleaning (FIGS. 11B and 12B) under the fifth condition, and a sixth cleaning (FIGS. 11C and 12C) under the sixth condition are sequentially performed. In this case, the side surface Fa, the lower surface Fb, and the side surface Fc in the gap F can be sequentially cleaned. By repeating the fourth cleaning, the fifth cleaning, and the sixth cleaning, the cleaning of the side surfaces Fa, the lower surface Fb, and the side surfaces Fc, and the cleaning of the side surfaces Fc, the lower surface Fb, and the side surfaces Fa can be repeated in the gap F. Accordingly, it is possible to prevent the deposits D from adhering to the gap F, and to improve the cleaning efficiency.

In the present embodiment, when controlling the thickness dc of the inner sheath Sc and the thickness dd of the outer sheath Sd, both the chunk DC voltage and the ring DC voltage are varied. However, one of the DC voltages may be fixed, and the other DC voltage may be varied. Even in this case, the thickness ratio dc/dd of the sheath can be controlled, and as a result, the incidence direction of the ions to the gap F can be controlled.

In the above-described embodiment, the cleaning of the gap G between the inner upper electrode 130 and the outer upper electrode 131 and the cleaning of the gap F between the electrostatic chuck 1111 and the edge ring 113 may be individually performed, or may be performed at the same time.

Cleanings (for example, the fourth to sixth cleanings) may be performed on a gap formed between the edge ring 113 and the cover ring 114. In this case, a sheath of a plasma generated above the edge ring 113 will be referred to as an inner sheath, and a sheath of a plasma generated above the cover ring 114 will be referred to as an outer sheath. Since the DC voltage is applied only to the edge ring 113, only the thickness of the inner sheath above the edge ring 113 is variable. However, by varying a thickness ratio of the inner sheath to the outer sheath, the same effect as in the above-described embodiment can be obtained for the gap formed between the edge ring 113 and the cover ring 114.

In the shower head assembly 13, the above-described cleanings (for example, the first to third cleanings) may be performed on a gap formed between the upper electrode and an insulating ring (not illustrated) disposed at an outer periphery of the upper electrode. In this case, a sheath of a plasma generated below the upper electrode will be referred to as an inner sheath, and a sheath of a plasma generated below the insulating ring will be referred to as an outer sheath. Since the DC voltage is applied only to the upper electrode, only the thickness of the inner sheath below the upper electrode is variable. However, by varying a thickness ratio of the inner sheath to the outer sheath, the same effect as in the above-described embodiment can be obtained for the gap formed between the upper electrode and the insulating ring.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

The following configuration examples also fall within the technical scope of the present disclosure.
(1) A cleaning method for a plasma processing apparatus, the cleaning method including:
(a) introducing a cleaning gas into a chamber of the plasma processing apparatus;
(b) generating a plasma in the chamber to perform a first cleaning under a first condition; and
(c) generating a plasma in the chamber to perform a second cleaning under a second condition, in which
at least one of the first condition and the second condition is adjusted such that a first ratio of an inner sheath thickness to an outer sheath thickness in a sheath of the plasma generated in (b) and a second ratio of an inner sheath thickness to an outer sheath thickness in a sheath of the plasma generated in (c) are different from each other.
(2) The cleaning method for a plasma processing apparatus according to (1), in which
(b) and (c) are repeated.
(3) The cleaning method for a plasma processing apparatus according to (1) or (2), further including:
(d) switching from (b) to (c), and in stages varying a sheath thickness of the plasma from the first ratio to the second ratio.
(4) The cleaning method for a plasma processing apparatus according to any one of (1) to (3), further including:
(e) switching from (c) to (b), and in stages varying a sheath thickness of the plasma from the second ratio to the first ratio.
(5) The cleaning method for a plasma processing apparatus according to any one of (1) to (4), in which
the first cleaning in (b) and the second cleaning in (c) are performed on a gap between an inner upper electrode and an outer upper electrode in the plasma processing apparatus.
(6) The cleaning method for a plasma processing apparatus according to (5), in which
at least one of the first condition and the second condition is adjusted by controlling a self-bias voltage of at least one of the inner upper electrode and the outer upper electrode.
(7) The cleaning method for a plasma processing apparatus according to (6), in which
at least one of the first condition and the second condition is adjusted by controlling a DC voltage applied to at least one of the inner upper electrode and the outer upper electrode.
(8) The cleaning method for a plasma processing apparatus according to (5), in which
at least one of the first condition and the second condition is adjusted by controlling a plasma density below at least one of the inner upper electrode and the outer upper electrode.
(9) The cleaning method for a plasma processing apparatus according to any one of (5) to (8), in which
an auxiliary gas is supplied to the gap in at least one of (b) and (c).
(10) The cleaning method for a plasma processing apparatus according to (9), in which
the auxiliary gas is the same type of gas as the cleaning gas.
(11) The cleaning method for a plasma processing apparatus according to any one of (1) to (4), in which
the first cleaning in (b) and the second cleaning in (c) are performed on a gap between an electrostatic chuck and an edge ring in the plasma processing apparatus.
(12) The cleaning method for a plasma processing apparatus according to any one of (1) to (4), in which
the first cleaning in (b) and the second cleaning in (c) are performed on a gap between an edge ring and a cover ring in the plasma processing apparatus.
(13) The cleaning method for a plasma processing apparatus according to any one of (1) to (4), in which
the first cleaning in (b) and the second cleaning in (c) are performed on a gap between an upper electrode and an insulating ring disposed at an outer periphery of the upper electrode in the plasma processing apparatus.

1. A cleaning method for a plasma processing apparatus, the cleaning method comprising:
(a) introducing a cleaning gas into a chamber of the plasma processing apparatus;
(b) generating a plasma in the chamber to perform a first cleaning under a first condition; and
(c) generating an other plasma in the chamber to perform a second cleaning under a second condition, wherein
at least one of the first condition and the second condition is adjusted such that a first ratio of an inner sheath thickness to an outer sheath thickness in a sheath of the plasma generated in (b) and a second ratio of an inner sheath thickness to an outer sheath thickness in a sheath of the other plasma generated in (c) are different from each other.

2. The cleaning method for a plasma processing apparatus according to claim 1, wherein
(b) and (c) are repeated.

3. The cleaning method for a plasma processing apparatus according to claim 1, further comprising:
(d) switching from (b) to (c), and in stages varying a sheath thickness of the plasma from the first ratio to the second ratio.

4. The cleaning method for a plasma processing apparatus according to claim 1, further comprising:
(e) switching from (c) to (b), and in stages varying a sheath thickness of the plasma from the second ratio to the first ratio.

5. The cleaning method for a plasma processing apparatus according to claim 1, wherein
the first cleaning in (b) and the second cleaning in (c) are performed on a gap between an inner upper electrode and an outer upper electrode in the plasma processing apparatus.

6. The cleaning method for a plasma processing apparatus according to claim 5, wherein
at least one of the first condition and the second condition is adjusted by controlling a self-bias voltage of at least one of the inner upper electrode and the outer upper electrode.

7. The cleaning method for a plasma processing apparatus according to claim 6, wherein
at least one of the first condition and the second condition is adjusted by controlling a DC voltage applied to at least one of the inner upper electrode and the outer upper electrode.

8. The cleaning method for a plasma processing apparatus according to claim 5, wherein
at least one of the first condition and the second condition is adjusted by controlling a plasma density below at least one of the inner upper electrode and the outer upper electrode.

9. The cleaning method for a plasma processing apparatus according to claim 5, wherein
an auxiliary gas is supplied to the gap in at least one of (b) and (c).

10. The cleaning method for a plasma processing apparatus according to claim 9, wherein
the auxiliary gas is a same type of gas as the cleaning gas.

11. The cleaning method for a plasma processing apparatus according to claim 1, wherein
the first cleaning in (b) and the second cleaning in (c) are performed on a gap between an electrostatic chuck and an edge ring in the plasma processing apparatus.

12. The cleaning method for a plasma processing apparatus according to claim 1, wherein
the first cleaning in (b) and the second cleaning in (c) are performed on a gap between an edge ring and a cover ring in the plasma processing apparatus.

13. The cleaning method for a plasma processing apparatus according to claim 1, wherein
the first cleaning in (b) and the second cleaning in (c) are performed on a gap between an upper electrode and an insulating ring disposed at an outer periphery of the upper electrode in the plasma processing apparatus.

14. The cleaning method for a plasma processing apparatus according to claim 2, further comprising:
(d) switching from (b) to (c), and in stages varying a sheath thickness of the plasma from the first ratio to the second ratio.

15. The cleaning method for a plasma processing apparatus according to claim 2, further comprising:
(e) switching from (c) to (b), and in stages varying a sheath thickness of the plasma from the second ratio to the first ratio.

16. The cleaning method for a plasma processing apparatus according to claim 2, wherein
the first cleaning in (b) and the second cleaning in (c) are performed on a gap between an inner upper electrode and an outer upper electrode in the plasma processing apparatus.

17. The cleaning method for a plasma processing apparatus according to claim 2, wherein
the first cleaning in (b) and the second cleaning in (c) are performed on a gap between an electrostatic chuck and an edge ring in the plasma processing apparatus.

18. The cleaning method for a plasma processing apparatus according to claim 2, wherein
the first cleaning in (b) and the second cleaning in (c) are performed on a gap between an edge ring and a cover ring in the plasma processing apparatus.

19. The cleaning method for a plasma processing apparatus according to claim 2, wherein
the first cleaning in (b) and the second cleaning in (c) are performed on a gap between an upper electrode and an insulating ring disposed at an outer periphery of the upper electrode in the plasma processing apparatus.

20. A plasma processing apparatus comprising:
a chamber,
a gas supply configured to supply a cleaning gas into the chamber,
plasma generator circuitry configured to generate a plasma from the cleaning gas in the chamber, and
controller circuitry configured to control the gas supply and the plasma generator circuitry to
(a) introduce the cleaning gas into the chamber,
(b) generate a plasma in the chamber to perform a first cleaning under a first condition, and
(c) generate an other plasma in the chamber to perform a second cleaning under a second condition, wherein
the controller is configured to adjust at least one of the first condition and the second condition such that a first ratio of an inner sheath thickness to an outer sheath thickness in a sheath of the plasma generated in (b) and a second ratio of an inner sheath thickness to an outer sheath thickness in a sheath of the other plasma generated in (c) are different from each other.
